(19) United States
(12) Patent Application Publication
(10) Pub. No.: US 2025/0271293 A1
(43) Pub. Date: Aug. 28, 2025

(54) LEVEL SENSORS FOR PRECURSOR VESSELS AND RELATED SYSTEMS AND RELATED METHODS

(71) Applicant: ENTEGRIS, INC., Billerica, MA (US)

(72) Inventors: David W. Peters, Kingsland, TX (US); Bryan C. Hendrix, Danbury, CT (US); Sara Moghaddam, Leander, TX (US)

(21) Appl. No.: 19/060,613

(22) Filed: Feb. 21, 2025

Related U.S. Application Data
(60) Provisional application No. 63/557,259, filed on Feb. 23, 2024.

(51) Int. Cl. G01F 23/72; C23C 16/52

(52) U.S. Cl. CPC G01F 23/72; C23C 16/52

(57) ABSTRACT

Some embodiments of the present disclosure relate to a system, comprising a vessel; at least one tray located in the vessel; a tube extending into the vessel to a location beneath the at least one tray; and a level sensor comprising: at least one reed switch located on the tube; and at least one toroidal magnet, wherein the tube extends through an opening defined by the at least one toroidal magnet, such that the at least one toroidal magnet is slidably engaged with the tube; wherein, when a solid precursor is loaded onto the at least one tray, the at least one toroidal magnet is configured to rest on a surface of the solid precursor; wherein the level sensor is configured to sense changes in the location of the at least one toroidal magnet relative to the at least one reed switch to sense precursor levels within the vessel. Also described is a vessel for delivering solid precursor vapor where a sensor or heater is connected through a gas exchange port of the vessel.

### CROSS-REFERENCE TO RELATED APPLICATIONS

This application claims the benefit under 35 USC 119 of U.S. Provisional Patent Application No. 63/557,259, filed Feb. 23, 2024, the disclosure of which is hereby incorporated herein by reference in its entirety.

### FIELD

The present disclosure relates to level sensors for precursor vessels, and related systems and related methods.

### BACKGROUND

Precursors contained in vessels are delivered to semiconductor tools. As the precursors are delivered, the vessels are depleted of the precursor.

It is desirable to know the amount of material remaining in a vessel connected to a Chemical Vapor Deposition (CVD) or Atomic Layer Deposition (ALD) delivery system. Running a source vessel dry can result in millions of dollars of ruined semiconductor wafers. Prematurely removing a container with a significant amount of remaining solid precursor may increase costs, waste valuable precursor, and produce unnecessary chemical waste that needs to be properly disposed.

### SUMMARY

Some embodiments of the present disclosure relate to a system, comprising a vessel; at least one tray located in the vessel; a tube extending into the vessel to a location beneath the at least one tray; and a level sensor comprising: at least one reed switch located on the tube; and at least one toroidal magnet, wherein the tube extends through an opening defined by the at least one toroidal magnet, such that the at least one toroidal magnet is slidably engaged with the tube; wherein, when a solid precursor is loaded onto the at least one tray, the at least one toroidal magnet is configured to rest on a surface of the solid precursor; wherein the level sensor is configured to sense changes in the location of the at least one toroidal magnet relative to the at least one reed switch to sense precursor levels within the vessel.

In some embodiments, the at least one toroidal magnet is enclosed in glass or stainless steel.

In some embodiments, the tube is configured for supplying a carrier gas to the location beneath the at least one tray.

In some embodiments, the at least one tray comprises: a first tray; and a second tray; wherein the at least one reed switch comprises: a first reed switch; and a second reed switch; wherein the at least one toroidal magnet comprises: a first toroidal magnet; and a second toroidal magnet; wherein the tube extends through a first opening defined by the first toroidal magnet and a second opening defined by the second toroidal magnet, such that the first toroidal magnet and the second toroidal magnet are independently slidably engaged with the tube; wherein, when a solid precursor is loaded onto the first tray, the first toroidal magnet is configured to rest on a surface of the solid precursor loaded onto the first tray; wherein, when a solid precursor is loaded onto the second tray, the second toroidal magnet is configured to rest on a surface of the solid precursor loaded onto the second tray; wherein the level sensor is configured to sense changes in the location of the first toroidal magnet relative to the first reed switch to sense precursor levels on the first tray; wherein the level sensor is configured to sense changes in the location of the second toroidal magnet relative to the second reed switch to sense precursor levels on the second tray.

In some embodiments, the at least one reed switch is mounted to an inner sidewall of the tube.

In some embodiments, an inner diameter of the at least one toroidal magnet is greater than an outer diameter of the tube.

In some embodiments, the system further comprises: a control device configured to receive and process signals from the at least one reed switch and to transmit a signal correlative to precursor levels.

Some embodiments of the present disclosure relate to a system comprising: a vessel; a tube extending into the vessel; and a level sensor comprising: at least one reed switch located on the tube; and at least one toroidal magnet, wherein the tube extends through an opening defined by the at least one toroidal magnet, such that the at least one toroidal magnet is slidably engaged with the tube; wherein, when a solid precursor is loaded into the vessel, the at least one toroidal magnet is configured to rest on a surface of the solid precursor; wherein the level sensor is configured to sense changes in a location of the at least one toroidal magnet relative to the at least one reed switch to sense precursor levels within the vessel.

In some embodiments, the system does not comprise a tray.

In some embodiments, the at least one toroidal magnet is enclosed in glass or stainless steel.

In some embodiments, the at least one reed switch is mounted to an inner sidewall of the tube.

In some embodiments, an inner diameter of the at least one toroidal magnet is greater than an outer diameter of the tube.

In some embodiments, the system further comprises: a control device configured to receive and process signals from the at least one reed switch and to transmit a signal correlative to precursor levels.

Some embodiments of the present disclosure relate to a vessel comprising: a vessel body; at least one tray located in the vessel body; a tube extending into the vessel body to a location beneath the at least one tray; a level sensor comprising: at least one reed switch located on the tube; and at least one toroidal magnet, wherein the tube extends through an opening defined by the at least one toroidal magnet, such that the at least one toroidal magnet is slidably engaged with the tube; wherein, when a solid precursor is loaded onto the at least one tray, the at least one toroidal magnet is configured to rest on a surface of the solid precursor; wherein the level sensor is configured to sense changes in the location of the at least one toroidal magnet relative to the at least one reed switch to sense precursor levels within the vessel.

In some embodiments, the at least one toroidal magnet is enclosed in glass or stainless steel.

In some embodiments, the tube is configured for supplying a carrier gas to the location beneath the at least one tray.

In some embodiments, the at least one tray comprises: a first tray; and a second tray; wherein the at least one reed switch comprises: a first reed switch; and a second reed switch; wherein the at least one toroidal magnet comprises: a first toroidal magnet; and a second toroidal magnet; wherein the tube extends through a first opening defined by the first toroidal magnet and a second opening defined by the second toroidal magnet, such that the first toroidal magnet and the second toroidal magnet are independently slidably engaged with the tube; wherein, when a solid precursor is loaded onto the first tray, the first toroidal magnet is configured to rest on a surface of the solid precursor loaded onto the first tray; wherein, when a solid precursor is loaded onto the second tray, the second toroidal magnet is configured to rest on a surface of the solid precursor loaded onto the second tray; wherein the level sensor is configured to sense changes in the location of the first toroidal magnet relative to the first reed switch to sense precursor levels on the first tray; wherein the level sensor is configured to sense changes in the location of the second toroidal magnet relative to the second reed switch to sense precursor levels on the second tray.

In some embodiments, the at least one reed switch is mounted to an inner sidewall of the tube.

In some embodiments, an inner diameter of the at least one toroidal magnet is greater than an outer diameter of the tube.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 depicts a non-limiting embodiment of a system, according to some embodiments.

FIG. 2 depicts a non-limiting top view of the system of FIG. 1, according to some embodiments.

FIG. 3 depicts a non-limiting embodiment of a system, according to some embodiments.

FIG. 4 depicts a non-limiting embodiment of a system, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Vessels containing a sublimation solid are used to supply a vapor in some vapor deposition tools. The vapor deposition tools use the supplied vapor, for example to deposit materials during the manufacture of, for example, semiconductor wafers. The vapor deposition tools may use deposition techniques, for example atomic layer deposition (ALD), plasma-enhanced chemical vapor deposition (PECVD), low-pressure chemical vapor deposition (LPCVD) or any combination of deposition methodologies. Current vessels include one or more surfaces, trays, or compartments to support powder, polycrystalline, or compressed forms of the sublimation solid, which sublimates to a vapor when the ampoule is heated. As vapor is provided to the deposition tool, the sublimation solid is consumed. Typically, ampoules are used for amounts of time based on predictions or models of consumption of the solids included therein. Should a sublimation solid run out during wafer processing, it may result in the wafers being scrapped.

Some embodiments relate to level sensors for sensing precursor levels within a vessel during, for example, semiconductor fabrication processes, among other things. The level sensors disclosed herein may be useful for determining when precursor levels within a vessel become low or approach empty. The level sensors disclosed herein improve the accuracy of measurements relating to the amount of precursor remaining in the vessel, thereby minimizing production interruptions, reducing the amount of wasted precursor, and reducing the amount of wasted wafers. The level sensors disclosed herein further overcome at least one challenge of conventional systems relating to the hysteresis and error, which is introduced by rigid, heated lines, that propagates into precursor level measurements when load cells are used. These and other advantages are apparent from the disclosed herein.

It may be useful to know the rate of consumption of chemical in a vessel. Being able to monitor the consumption rate, in real time, may allow the operator to tune the process and make it more efficient. Additionally, sudden changes in consumption can indicate a problem, such as a clogged delivery line, and enable the operator to take corrective action in a timely fashion and avoid having to scrap product.

The use of internal level sensors on solid delivery containers present a number of challenges. Delivery vessels containing liquid precursor may employ floats, optical or ultrasonic sensors, and/or load cells to monitor weight changes. For a number of reasons, these approaches do not readily translate to the solid precursors in delivery vessels. Solid precursor delivery requires elevated temperatures which necessitate rigid connecting tubes, generally wrapped with heating elements and/or insulation. The rigid connection between the system and the solids delivery vessel makes load cells or balances impractical.

Liquids always seek the same level, automatically redistributing to form a level upper surface. This property enables ultrasonic and optical sensors. In contrast, solids can sublimate in a non-uniform manner that leaves the sensor uncovered while still having a majority of material in the container. This non-uniformity may produce false readings, for example, having an optical or level sensor indicate the container is nearly empty while a sizeable amount of precursor remains.

Float sensors have been considered impractical for solid delivery containers due to the multiple tray geometry employed to maximize chemical flux. The trays present a physical barrier which prevents free movement of the float.

Herein is described a level sensor system employing multiple floats, for example, one for each tray. In addition, the carrier gas inlet tube serves two purposes: bringing carrier gas into the container and serving as a housing for the level sensor system.

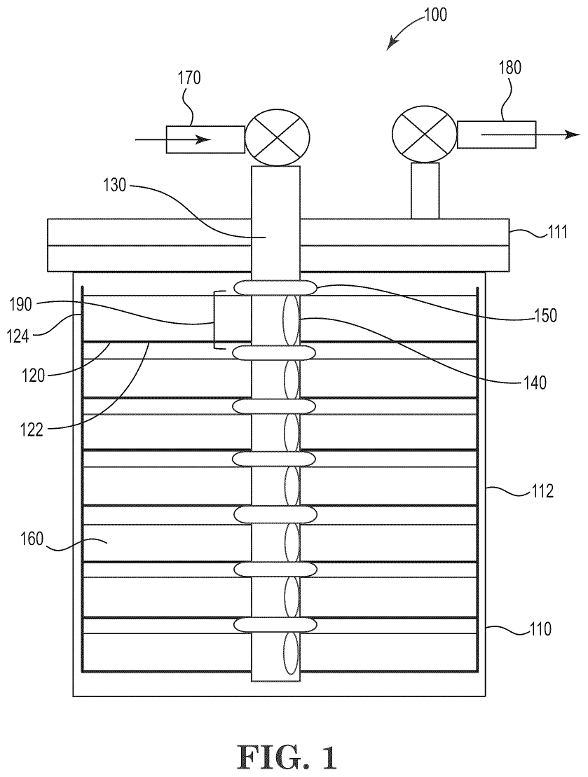

FIG. 1 is a non-limiting embodiment of the system described herein. As shown in FIG. 1, the system 100, includes a vessel 110 having an inlet and an outlet. The vessel 110 may define an interior volume. In some embodiments, the vessel 110 is fully enclosed. In some embodiments, the vessel 110 comprises a lid 111 coupled or removably coupled to a vessel body 112, wherein the lid 111, when mated with the vessel body 112, defines the interior volume of the vessel 110. In some embodiments, at least one of the inlet 170, the outlet 180, or any combination thereof, is located in the lid 111. The vessel 110 may contain or may be configured to contain a vaporizable precursor, which, when vaporized, produces a precursor vapor that is dischargeable through the outlet. The vaporizable precursor may comprise solid particulate matter, such as, for example and without limitation, solid particles in the form of a powder or chunks, among other forms. In some embodiments, the vessel 110 comprises at least one tray 120 located within the interior volume of the vessel 110. In some embodiments, the at least one tray 120 is configured to contain the vaporizable precursor. At least one of the at least one tray 120 may comprise a base 122, and a sidewall 124 extending upwards from an outer edge of the base 122. The at least one tray 120 may be configured to contact an inner surface of the vessel 110.

A tube 130 may extend into the vessel 110 to a location beneath the at least one tray 120. In some embodiments, the tube 130 extends to a location beneath the bottommost tray of the at least one tray 120. In some embodiments, the tube 130 extends to a location beneath at least one of the at least one tray 120, while at least one additional tray is further located beneath the tube 130. The tube 130 may extend through the lid 111 into the interior volume of the vessel 110, to the location beneath the at least one tray 120. In some embodiments, a first end of the tube 130 is connected to an inlet of the vessel 110. In some embodiments, a second end, which is opposite the first end, is located beneath the at least one tray. It will be appreciated that the location of the inlet and/or the first end of the tube is not particularly limited and that other configurations may be employed, without departing from the scope of this disclosure. For example, in some embodiments, the tube 130 may have a first end connected to an inlet that is located beneath the lid 111 and extends through a sidewall of the vessel body 112. Other configurations are contemplated and thus these shall not be limiting. In some embodiments, the tube 130 is configured to supply a gas, such as, a carrier gas, from a source to the interior volume of the vessel 110.

The system 100 comprises a level sensor. The level sensor may comprise at least one reed switch 140 and at least one toroidal magnet 150. In some embodiments, the at least one reed switch 140 is located on the tube 130. In some embodiments, for example the at least one reed switch 140 is located on an inner surface of the tube 130, wherein the inner surface of the tube 130 is a surface configured to directly contact a carrier gas flowing through the tube 130. In some embodiments, for example the at least one reed switch 140 is mounted to an inner surface of the tube 130, wherein the inner surface of the tube 130 is a surface configured to directly contact a carrier gas flowing through the tube 130. In some embodiments, the at least one reed switch 140 is located on an outer surface of the tube 130, wherein the outer surface of the tube 130 is a surface which would not directly contact a carrier gas flowing through the tube 130. In some embodiments, the at least one reed switch 140 is formed in the tube 130, between an inner surface of the tube 130 and an outer surface of the tube 130. In some embodiments, the at least one reed switch 140 is located on another surface, such as, for example and without limitation, a sidewall 124 of the at least one tray 120, a sidewall of the vessel body 112, among other locations. The at least one reed switch 140 may be positioned at a location sufficient for the level sensor to sense changes in the location of the at least one toroidal magnet. The at least one reed switch 140 may be adhered, bonded, secured, fastened (e.g., mechanically fastened), or otherwise attached to a surface.

The level sensor may comprise at least one toroidal magnet 150. The at least one toroidal magnet 150 may be positioned at a location sufficient for the at least one reed switch 140 to sense changes in the location of the at least one toroidal magnet. The at least one toroidal magnet 150 may be configured to move, relative to the at least one reed switch 140, while the precursor 160 is consumed (e.g., vaporized) during a semiconductor fabrication process, among other processes. In some embodiments, the tube 130 extends through an opening defined by the at least one toroidal magnet 150, such that the at least one toroidal magnet 150 is slidably engaged with the tube 130. In some embodiments, when a solid precursor 160 is loaded onto the at least one tray, or when a solid precursor 160 is loaded into the vessel 110, the at least one toroidal magnet is configured to rest on a surface of the solid precursor 160. With the at least one toroidal magnet 150 being slidably engaged with the tube 130 and also resting on a surface of the solid precursor 160, the at least one toroidal magnet 150 may move vertically downward as the solid precursor 160 is consumed. In some embodiments, the movement of the at least one toroidal magnet 150 in the vertical downward direction is sensed by the level sensor and correlated to precursor levels within the vessel 110 or to precursor levels on the at least one tray 120. In some embodiments, level sensor is configured to sense changes in the location of the at least one toroidal magnet 150 relative to the at least one reed switch 140 to sense precursor 160 levels within the vessel.

The at least one toroidal magnet 150 may be covered by a coating or is enclosed in a material. In some embodiments, the at least one toroidal magnet 150 comprises a coating configured to protect against the conditions present in the vessel during operation. In some embodiments, the at least one toroidal magnet 150 is enclosed in a material that is configured to protect against the conditions present in the vessel during operation. In some embodiments, the at least one toroidal magnet 150 comprises a coating configured to reduce or avoid contamination of the precursor vapor during operation. In some embodiments, the at least one toroidal magnet 150 is enclosed in a material configured to reduce or avoid contamination of the precursor vapor during operation. In some embodiments, the at least one toroidal magnet 150 is enclosed in glass or stainless steel. In some embodiments, the at least one toroidal magnet 150 is enclosed in an inert material. In some embodiments, the inert material comprises a material that does not react with the precursor and/or the vaporized precursor and/or that does not otherwise contaminant the precursor and/or the vaporized precursor.

The at least one toroidal magnet may have an inner diameter and an outer diameter. In some embodiments, the inner diameter of the at least one toroidal magnet 150 is greater than an outer diameter of the tube 130. In some embodiments, the outer diameter of the at least one toroidal magnet 150 is less than an inner diameter of the vessel 110.

In some embodiments, the system 100 may comprise a plurality of trays, a plurality of reed switches, and a plurality of toroidal magnets. In some embodiments, the system 100 comprises a reed switch and a toroidal magnet for each tray present within the vessel 110. In some embodiments, for example, the system 100 comprises a first tray, a second tray, a first reed switch, a second reed switch, a first toroidal magnet, and a second toroidal magnet. In some embodiments, the tube 130 extends through a first opening defined by the first toroidal magnet and a second opening defined by the second toroidal magnet, such that the first toroidal magnet and the second toroidal magnet are independently slidably engaged with the tube 130. In some embodiments, wherein, when a solid precursor 160 is loaded onto the first tray, the first toroidal magnet is configured to rest on a surface of the solid precursor 160 loaded onto the first tray. In some embodiments, when the solid precursor 160 is loaded onto the second tray, the second toroidal magnet is configured to rest on a surface of the solid precursor 160 loaded onto the second tray. In some embodiments, the level sensor is configured to sense changes in the location of the first toroidal magnet relative to the first reed switch to sense precursor levels 190 on the first tray. In some embodiments, the level sensor is configured to sense changes in the location of the second toroidal magnet relative to the second reed switch to sense precursor levels 190 on the second tray.

In some embodiments, the level sensor is located at the uppermost tray. For example, in some embodiments, the reed switch and the toroidal magnet are located on the tube 130 such that, when the solid precursor 160 is loaded in the vessel 110, the toroidal magnet is configured to rest on a surface of the solid precursor 160 loaded onto the uppermost tray and the level sensor is configured to sense changes in the location of the toroidal magnet relative to the reed switch to sense precursor levels 190 on the uppermost tray. In some embodiments, the precursor levels 190 on the uppermost tray is representative of the precursor levels 190 on the other trays in the vessel 110.

In some embodiments, the level sensor is located at the bottommost tray. For example, in some embodiments, the reed switch and the toroidal magnet are located on the tube 130 such that, when the solid precursor 160 is loaded in the vessel 110, the toroidal magnet is configured to rest on a surface of the solid precursor 160 loaded onto the bottommost tray and the level sensor is configured to sense changes in the location of the toroidal magnet relative to the reed switch to sense precursor levels 190 on the bottommost tray. In some embodiments, the precursor levels 190 on the bottommost tray is representative of the precursor levels 190 on the other trays in the vessel 110.

In some embodiments, the level sensor is located at the intermediate tray, wherein the intermediate tray is a tray that is not the uppermost tray and that is not the bottommost tray. For example, in some embodiments, the reed switch and the toroidal magnet are located on the tube 130 such that, when the solid precursor 160 is loaded in the vessel 110, the toroidal magnet is configured to rest on a surface of the solid precursor 160 loaded onto the intermediate tray and the level sensor is configured to sense changes in the location of the toroidal magnet relative to the reed switch to sense precursor levels 190 on the intermediate tray. In some embodiments, the precursor levels 190 on the bottommost tray is representative of the precursor levels 190 on the other trays in the vessel 110.

In some embodiments, the system 100 further comprises a control device configured to receive and process signals from the at least one reed switch 140 and to transmit a signal correlative to precursor levels 190. In some embodiments, when the precursor levels 190 are below a threshold level, the control device is configured to send an alert signal indicating the vessel 110 needs to be refilled with solid precursor 160. In some embodiments, when the precursor levels 190 are above a threshold level, the control device is configured to send a signal indicating the precursor levels 190 within the vessel 110 are adequate.

In some embodiments, the at least one tray 120 is optional. For example, in some embodiments, the system 100 does not comprise the at least one tray 120.

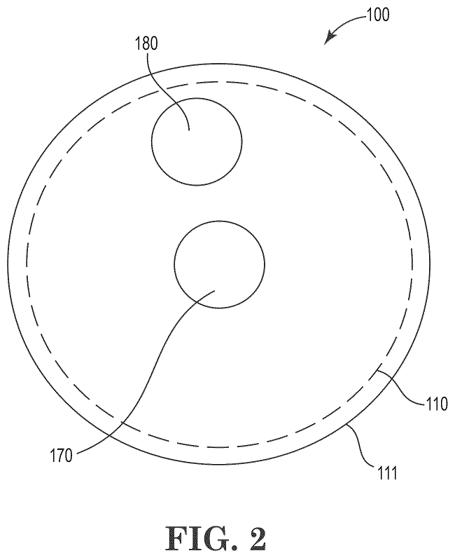

FIG. 2 is a non-limiting top view of the system depicted in FIG. 1. As shown in FIG. 2, the system 100 includes a vessel 110, a lid 111, a carrier gas inlet 170, and a vapor outlet 180.

As shown in FIG. 2, the vessel 110 includes the lid 111 placed on the vessel 110. The lid 111 includes the vapor outlet 180 and the carrier gas inlet 170. The carrier gas inlet 170 may extend into the vessel 110 by tube 130. The vapor outlet 180 may include a controllable valve to regulate the flow of vapor from the at least one tray 120. In some embodiments, the vapor outlet 180 includes venturi tubes. In some embodiments, the tube 130 is affixed to the lid 111.

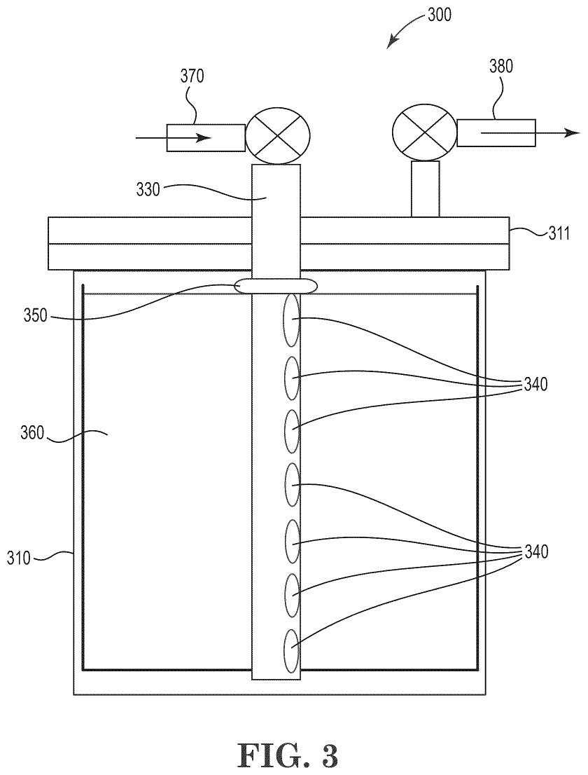

FIG. 3 is a non-limiting embodiment of a system 300, according to some embodiments. The system 300 is similar to the other systems disclosed herein, except the system does not comprise a plurality of trays. The system 300 is trayless. For simplicity, not all similar or same features are discussed. However, it will be appreciated that the system 300 may have any one or more of the features disclosed herein without departing from the scope of this disclosure. As shown in FIG. 3, the system 300 comprises a vessel 310, and a lid 311 coupled or removably coupled to the vessel 310. The lid 311, when mated with the vessel 310, defines an interior volume of the vessel 310. A tube 330 extends through the lid 311 into the interior volume of the vessel 310 to a location above an inner bottom surface of the vessel 310. A plurality of reed switches 340 are located along a length of the tube 330. A toroidal sensor 350 is shown resting on a surface of a precursor 360. The tube 330 extends through an inner diameter of the toroidal sensor 350, such that, as the precursor 360 is depleted, the toroidal sensor 350 traverses downward along the length of the tube 330. Each of the reed switches 340 are located at various locations along the length of the tube 330 so as to allow for sensing of the precursor level within the vessel as the precursor 360 is depleted or consumed. The number of reed switches 340 may be increased or decreased to achieve a desired sensitivity. Also shown is an inlet 370 and an outlet 380.

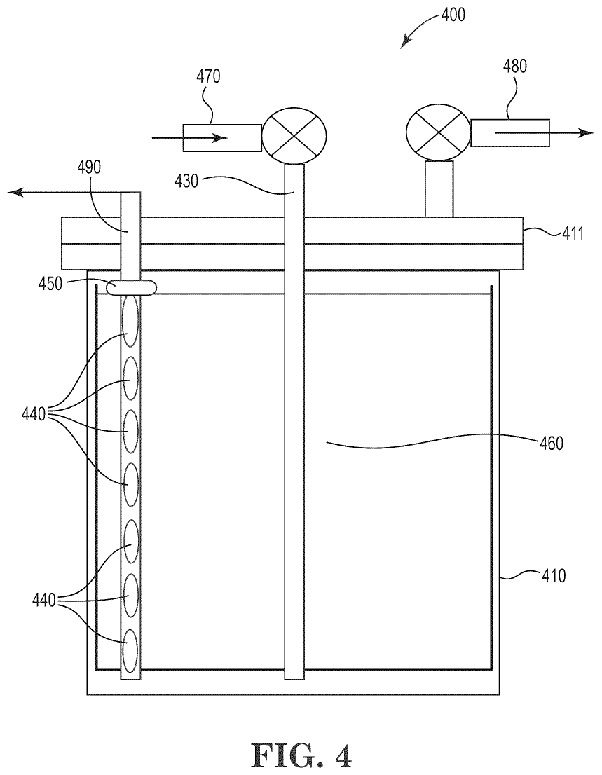

FIG. 4 is a non-limiting embodiment of a system 400, according to some embodiments. The system 400 is similar to the other systems disclosed herein, except the level sensor (e.g., reed switches and/or toroidal magnet) is not coaxial with the tube 430. For simplicity, not all similar or same features are discussed. However, it will be appreciated that the system 400 may have any one or more of the features disclosed herein without departing from the scope of this disclosure. For example, although shown without trays, it will be appreciated that the system can comprise trays, among other things. As shown in FIG. 4, the system 400 comprises a vessel 410, and a lid 411 coupled or removably coupled to the vessel 410. The lid 411, when mated with the vessel 410, defines an interior volume of the vessel 410. A tube 430 extends through the lid 411 into the interior volume of the vessel 410 to a location above an inner bottom surface of the vessel 410. A plurality of reed switches 440 are located along a length of a second tube 490. The second tube 490 is different from the tube 330, which may deliver a carrier gas. As shown, the second tube 490 is not aligned on a central axis of the vessel 410. The location of the second tube 490 is not particularly limited and can be closer to the sidewall of the vessel 410 or closer to the tube 430, or any one or more locations therebetween. A toroidal sensor 450 is shown resting on a surface of a precursor 460. The second tube 490 extends through an inner diameter of the toroidal sensor 450, such that, as the precursor 460 is depleted, the toroidal sensor 450 traverses downward along the length of the second tube 490. Each of the reed switches 440 are located at various locations along the length of the tube 430 so as to allow for sensing of the precursor level within the vessel as the precursor 460 is depleted or consumed. The number of reed switches 440 may be increased or decreased to achieve a desired sensitivity. Also shown is an inlet 470 and an outlet 480, with the inlet 470 coupled to the tube 430.

The vessels disclosed herein may be employed in deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

In some embodiments, the precursor comprises at least one of dimethyl hydrazine, trimethyl aluminum (TMA), hafnium chloride (HfCI₄), zirconium chloride (ZrCl₄), indium trichloride, indium monochloride, aluminum trichloride, titanium iodide, tungsten carbonyl, Ba(DPM)₂, bis dipivaloyl methanato strontium (Sr(DPM)₂), TiO(DPM)₂, tetra dipivaloyl methanato zirconium (Zr(DPM)₄), decaborane, octadecaborane, boron, magnesium, gallium, indium, antimony, copper, phosphorous, arsenic, lithium, sodium tetrafluoroborates, precursors incorporating alkyl-amidinate ligands, organometallic precursors, zirconium tertiary butoxide (Zr(t-OBu)₄), tetrakisdiethylaminozirconium (Zr(Net₂)₄), tetrakisdiethylaminohafnium (Hf(Net₂)₄), tetrakis(dimethylamino) titanium (TDMAT), tertbutyliminotris(diethylamino) tantalum (TBTDET), pentakis (dimethylamino) tantalum (PDMAT), pentakis (ethylmethylamino) tantalum (PEMAT), tetrakisdimethylaminozirconium (Zr(NMe₂)₄), hafniumtertiarybutoxide (Hf(tOBu)₄), xenon difluoride (XeF₂), xenon tetrafluoride (XeF₄), xenon hexafluoride (XeF₆), or any combination thereof.

In some embodiments, the precursor comprises at least one of decaborane, hafnium tetrachloride, zirconium tetrachloride, indium trichloride, metalorganic β-diketonate complexes, tungsten hexafluoride, cyclopentadienylcycloheptatrienyl-titanium (CpTiCht), aluminum trichloride, titanium iodide, cyclooctatetraenecyclo-pentadienyltitanium, biscyclopentadienyltitaniumdiazide, trimethyl gallium, trimethyl indium, aluminum alkyls like trimethylaluminum, triethylaluminum, trimethylamine alane, dimethyl zinc, tetramethyl tin, trimethyl antimony, diethyl cadmium, tungsten carbonyl, or any combination thereof.

In some embodiments, the precursor comprises at least one of elemental metal, metal halides, metal oxyhalides, metalorganic complexes, or any combination thereof. For example, in some embodiments, the precursor material comprises, consists of, or consists essentially of, or is selected from the group consisting of, at least one of elemental boron, copper, phosphorus, decaborane, gallium halides, indium halides, antimony halides, arsenic halides, gallium halides, aluminum iodide, titanium iodide, MoO₂Cl₂, MoOCl₄, MoCl₅, WCl₅, WOCl₄, WCl₆, cyclopentadienylcycloheptatrienyltitanium (CpTiCht), cyclooctatetraenecyclopenta-dienyltitanium, biscyclopentadienyltitanium-diazide, In(CH₃)₂ (hfac), dibromomethyl stibine, tungsten carbonyl, metalorganic β-diketonate complexes, metalorganic alkoxide complexes, metalorganic carboxylate complexes, metalorganic aryl complexes, metalorganic amido complexes, or any combination thereof.

In some embodiments, the precursor comprises at least one of any type of source material that can be liquefied either by heating or solubilization in a solvent including, for example and without limitation, at least one of decaborane, (B₁₀H₁₄), pentaborane (B₅H₉), octadecaborane (B1₈H₂₂), boric acid (H₃BO₃), SbCl₃, SbCl₅, or any combination thereof. In some embodiments, the precursor comprises at least one of at least one of AsCl₃, AsBr₃, AsF₃, AsF₅, AsH₃, AS₄O₆, As₂Se₃m As₂S₂, As₂S₅, As₂S₅, As₂Te₃, B₄H₁₁, B₄H₁₀, B₃H₆N₃, BBr₃, BCl₃, BF₃, BF₃·O(C₂H₅)₂, BF₃·HOCH₃, B₂H₆, F₂, HF, GeBr₄, GeCl₄, GeF₄, GeH₄, H₂, HCl, H₂Se, H₂Te, H₂S, WF₆, SiH₄, SiH₂Cl₂, SiHCI₃, SiCl₄, SiH₃Cl, NH₃, NH₃, Ar, Br₂, HBr, BrF₅, CO₂, CO, COCl₂, COF₂, Cl₂, CIF₃, CF₄, C₂F₆, C₃F₈, C₄F₈, C₅F₈, CHF₃, CH₂F₂, CH₃F, CH₄, SiH₆, He, HCN, Kr, Ne, Ni(CO)₄, HNO₃, NO, N₂, NO₂, NF₃, N₂O, C₈H₂₄O₄Si₄, PH₃, POCl₃, PCl₅, PF₃, PFS, SbH₃, SO₂, SF₆, SF₄, Si(OC₂H₅)₄, C₄H₁₆Si₄O₄, Si(CH₃)₄, SiH(CH₃)₃, TiCl₄, Xe, SiF₄, WOF₄, TaBr₅, TaCl₅, TaF₅, Sb(C₂H₅)₃, Sb(CH₃)₃, In(CH₃)₃, PBr₅, PBr₃, RuF₅, or any combination thereof.

The described implementations use one or both of the gas exchange ports for the dual purposes of providing gas exchange and providing communication and/or power to the sensor and/or heating elements in the solid precursor delivery vessel. Solid precursor delivery vessels include an outlet port which is connected, either directly or indirectly, to the processing chamber. Vaporized solid precursor flows through the outlet port providing the material for deposition and layer formation on the substrates. To prevent condensation of the precursor vapor, the lines connecting the outlet port to the deposition chamber may be heated.

In one embodiment, the solid precursor delivery vessel includes a gas inlet port. The gas inlet port may serve also contain connections for the level sensor system described and/or one or more internal heaters. The gas inlet port is used to provide a carrier gas to the solid precursor delivery vessel. The carrier gas, which is often an inert gas, may help sublimate the solid precursor, enhance temperature uniformity in the solid precursor delivery vessel, and/or provide other benefits to delivery and deposition of solid precursors.

Solid precursor delivery vessels may be operated at below atmospheric pressure due to the vapor pressures of the heated solid precursor. This pressure may be increased by a carrier gas. However, generally in CVD and ALD, the operating pressure is significantly below ambient atmospheric pressure. The need to maintain good vacuum pressure and minimize leaks may be important to reliable and consistent functioning of a vapor deposition system. The delivery vessel is heated to sublimate the solid precursor, this heating may challenge the ability of connections to the vessel to stay air tight. It follows that the more openings in a vessel, the more potential points of failure exist for the vacuum. Previous work such as, for example, U.S. Patent Application Publication No. 2021/0123134 has disclosed a system that uses dedicated ports to communicate with internal sensors capable of monitoring solid precursor levels. In contrast, the present disclosure relies on providing the connections through the gas exchange port or ports. The present approach may eliminate the need for additional, dedicated ports for sensors or internal heaters. In some embodiments, this may decrease the potential points of failure of the system and enhance reliability compared with previously known designs.

In some embodiments, locating the pass through for sensor line or power line into the vacuum in the carrier gas supply portion of the vapor deposition system may avoid thermally cycling this interface, improving its air tightness and reducing the opportunities for failure.

### ASPECTS

Various Aspects are described below. It is to be understood that any one or more of the features recited in the following Aspect(s) can be combined with any one or more other Aspect(s).

Aspect 1. A system, comprising:
a vessel;
at least one tray located in the vessel;
a tube extending into the vessel to a location beneath the at least one tray, the tube connecting an interior of the vessel with a gas handling system; and
a level sensor comprising:
   at least one reed switch located on the tube; and
   at least one toroidal magnet,
      wherein the tube extends through an opening defined by the at least one toroidal magnet, such that the at least one toroidal magnet is slidably engaged with the tube;
      wherein, when a solid precursor is loaded onto the at least one tray, the at least one toroidal magnet is configured to rest on a surface of the solid precursor;
wherein the level sensor is configured to sense changes in the location of the at least one toroidal magnet relative to the at least one reed switch to sense precursor levels within the vessel.

Aspect 2. The system according to Aspect 1, wherein the at least one toroidal magnet is enclosed in glass or stainless steel.

Aspect 3. The system according to any one of Aspects 1-2, wherein the tube is configured for supplying a carrier gas to the location beneath the at least one tray.

Aspect 4. The system according to any one of Aspects 1-3,
wherein the at least one tray comprises:
   a first tray; and
   a second tray;
wherein the at least one reed switch comprises:
   a first reed switch; and
   a second reed switch;
wherein the at least one toroidal magnet comprises:
   a first toroidal magnet; and
   a second toroidal magnet;
      wherein the tube extends through a first opening defined by the first toroidal magnet and a second opening defined by the second toroidal magnet, such that the first toroidal magnet and the second toroidal magnet are independently slidably engaged with the tube;
      wherein, when a solid precursor is loaded onto the first tray, the first toroidal magnet is configured to rest on a surface of the solid precursor loaded onto the first tray;
      wherein, when a solid precursor is loaded onto the second tray, the second toroidal magnet is configured to rest on a surface of the solid precursor loaded onto the second tray;
      wherein the level sensor is configured to sense changes in the location of the first toroidal magnet relative to the first reed switch to sense precursor levels on the first tray;
      wherein the level sensor is configured to sense changes in the location of the second toroidal magnet relative to the second reed switch to sense precursor levels on the second tray.

Aspect 5. The system according to any one of Aspects 1-4, wherein the at least one reed switch is mounted to an inner sidewall of the tube.

Aspect 6. The system according to any one of Aspects 1-5, wherein an inner diameter of the at least one toroidal magnet is greater than an outer diameter of the tube.

Aspect 7. The system according to any one of Aspects 1-6, further comprising:
a control device configured to receive and process signals from the at least one reed switch and to transmit a signal correlative to precursor levels.

Aspect 8. A system comprising:
a vessel;
a tube extending into the vessel, the tube connecting an interior of the vessel with a gas handling system; and
a level sensor comprising:
   at least one reed switch located on the tube; and
   at least one toroidal magnet,
      wherein the tube extends through an opening defined by the at least one toroidal magnet, such that the at least one toroidal magnet is slidably engaged with the tube;
      wherein, when a solid precursor is loaded into the vessel, the at least one toroidal magnet is configured to rest on a surface of the solid precursor;
wherein the level sensor is configured to sense changes in a location of the at least one toroidal magnet relative to the at least one reed switch to sense precursor levels within the vessel.

Aspect 9. The system according to Aspects 8, wherein the system does not comprise a tray.

Aspect 10. The system according to any one of Aspects 8-9, wherein the at least one toroidal magnet is enclosed in glass or stainless steel.

Aspect 11. The system according to any one of Aspects 8-10, wherein the at least one reed switch is mounted to an inner sidewall of the tube.

Aspect 12. The system according to any one of Aspects 8-11, wherein an inner diameter of the at least one toroidal magnet is greater than an outer diameter of the tube.

Aspect 13. The system according to any one of Aspects 8-12, further comprising:
a control device configured to receive and process signals from the at least one reed switch and to transmit a signal correlative to precursor levels.

Aspect 14. A vessel comprising:
a vessel body;
at least one tray located in the vessel body;
a tube extending into the vessel body to a location beneath the at least one tray, the tube connecting an interior of the vessel with a gas handling system;
a level sensor comprising:
   at least one reed switch located on the tube; and
   at least one toroidal magnet,
      wherein the tube extends through an opening defined by the at least one toroidal magnet, such that the at least one toroidal magnet is slidably engaged with the tube;
      wherein, when a solid precursor is loaded onto the at least one tray, the at least one toroidal magnet is configured to rest on a surface of the solid precursor;
wherein the level sensor is configured to sense changes in the location of the at least one toroidal magnet relative to the at least one reed switch to sense precursor levels within the vessel.

Aspect 15. The system according to Aspects 14, wherein the at least one toroidal magnet is enclosed in an inert material.

Aspect 16. The system according to any one of Aspects 14-15, wherein the at least one toroidal magnet is enclosed in glass or stainless steel.

Aspect 17. The system according to any one of Aspects 14-16, wherein the tube is configured for supplying a carrier gas to the location beneath the at least one tray.

Aspect 18. The system according to any one of Aspects 14-17,
wherein the at least one tray comprises:
   a first tray; and
   a second tray;
wherein the at least one reed switch comprises:
   a first reed switch; and
   a second reed switch;
wherein the at least one toroidal magnet comprises:
   a first toroidal magnet; and
   a second toroidal magnet;
      wherein the tube extends through a first opening defined by the first toroidal magnet and a second opening defined by the second toroidal magnet, such that the first toroidal magnet and the second toroidal magnet are independently slidably engaged with the tube;
      wherein, when a solid precursor is loaded onto the first tray, the first toroidal magnet is configured to rest on a surface of the solid precursor loaded onto the first tray;
      wherein, when a solid precursor is loaded onto the second tray, the second toroidal magnet is configured to rest on a surface of the solid precursor loaded onto the second tray;
      wherein the level sensor is configured to sense changes in the location of the first toroidal magnet relative to the first reed switch to sense precursor levels on the first tray;
      wherein the level sensor is configured to sense changes in the location of the second toroidal magnet relative to the second reed switch to sense precursor levels on the second tray.

Aspect 19. The system according to any one of Aspects 14-18, wherein the at least one reed switch is mounted to an inner sidewall of the tube.

Aspect 20. The system according to any one of Aspects 14-19, wherein an inner diameter of the at least one toroidal magnet is greater than an outer diameter of the tube.

Aspect 21. The system according to any one of Aspects 14-20, wherein the only communication ports through the vessel are used for gas handling

Aspect 22. The system according any one of Aspects 14-21, wherein the level sensor communicates with a controller via a gas port.

Aspect 23. The system according to any one of Aspects 8-13, wherein the only openings in the vessel are used to either provide carrier gas to the vessel or remove gas from the vessel.

Aspect 24. The system according any one of Aspects 8-13 or 23, wherein the level sensor communicates with a controller via a gas port.

Aspect 25. The system according to any one of Aspects 1-7, wherein the only openings in the vessel are used to either provide carrier gas to the vessel or remove gas from the vessel.

Aspect 26. The system according any one of Aspects 1-7 or 25, wherein the level sensor communicates with a controller via a gas port.

Aspect 27. The system according to any one of Aspects 1-7 or 25-26, further comprising an internal heater, where the internal heater is provided power via a gas port.

Aspect 28. A vessel for containing and delivering solid precursor comprising:
a plurality of trays supporting the solid precursor;
an inlet port to provide carrier gas to an interior of the vessel;
an outlet port to receive carrier gas and vaporized solid precursor from the vessel;
a wired connection through the inlet port or the outlet port, the wired connection providing communication and/or power to at least one of: a sensor to measure an amount of the solid precursor remaining in the vessel and an internal heater to provide heat to promote sublimation of the solid precursor.

Aspect 29. The vessel of Aspect 28, where the wired connection is through the inlet port.

Aspect 30. The vessel of Aspect 28 or 29, where the wired connection provides communication for a sensor.

Aspect 31. The vessel of Aspect 30, wherein the sensor is a reed sensor utilizing disk or float comprising a magnet.

Aspect 32. The vessel of Aspect 31, wherein the magnet is a toroidal magnet.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A system, comprising:
a vessel;
at least one tray located in the vessel;
a tube extending into the vessel to a location beneath the at least one tray the tube providing gas exchange between the vessel and a connected gas handling system; and
a level sensor comprising:
at least one reed switch located on the tube; and
at least one toroidal magnet,
wherein the tube extends through an opening defined by the at least one toroidal magnet, such that the at least one toroidal magnet is slidably engaged with the tube;
wherein, when a solid precursor is loaded onto the at least one tray, the at least one toroidal magnet is configured to rest on a surface of the solid precursor;
wherein the level sensor is configured to sense changes in the location of the at least one toroidal magnet relative to the at least one reed switch to sense precursor levels within the vessel.

2. The system of claim 1, wherein the at least one toroidal magnet is enclosed in an inert material.

3. The system of claim 1, wherein the tube is configured for supplying a carrier gas to the location beneath the at least one tray.

4. The system of claim 1,
wherein the at least one tray comprises:
a first tray; and
a second tray;
wherein the at least one reed switch comprises:
a first reed switch; and
a second reed switch;
wherein the at least one toroidal magnet comprises:
a first toroidal magnet; and
a second toroidal magnet;
wherein the tube extends through a first opening defined by the first toroidal magnet and a second opening defined by the second toroidal magnet, such that the first toroidal magnet and the second toroidal magnet are independently slidably engaged with the tube;
wherein, when a solid precursor is loaded onto the first tray, the first toroidal magnet is configured to rest on a surface of the solid precursor loaded onto the first tray;
wherein, when a solid precursor is loaded onto the second tray, the second toroidal magnet is configured to rest on a surface of the solid precursor loaded onto the second tray;
wherein the level sensor is configured to sense changes in the location of the first toroidal magnet relative to the first reed switch to sense precursor levels on the first tray;
wherein the level sensor is configured to sense changes in the location of the second toroidal magnet relative to the second reed switch to sense precursor levels on the second tray.

5. The system of claim 1, wherein the at least one reed switch is mounted to an inner sidewall of the tube.

6. The system of claim 1, wherein an inner diameter of the at least one toroidal magnet is greater than an outer diameter of the tube.

7. The system of claim 1, further comprising:
a control device configured to receive and process signals from the at least one reed switch and to transmit a signal correlative to precursor levels.

8. A system comprising:
a vessel;
a tube extending into the vessel; and
a level sensor comprising:
at least one reed switch located on the tube; and
at least one toroidal magnet,
wherein the tube extends through an opening defined by the at least one toroidal magnet, such that the at least one toroidal magnet is slidably engaged with the tube;
wherein, when a solid precursor is loaded into the vessel, the at least one toroidal magnet is configured to rest on a surface of the solid precursor;
wherein the level sensor is configured to sense changes in a location of the at least one toroidal magnet relative to the at least one reed switch to sense precursor levels within the vessel.

9. The system of claim 8, wherein the system does not comprise a tray.

10. The system of claim 8, wherein the at least one toroidal magnet is enclosed in an inert material.

11. The system of claim 8, wherein the at least one reed switch is mounted to an inner sidewall of the tube.

12. The system of claim 8, wherein an inner diameter of the at least one toroidal magnet is greater than an outer diameter of the tube.

13. The system of claim 8, further comprising:
a control device configured to receive and process signals from the at least one reed switch and to transmit a signal correlative to precursor levels.

14. A vessel comprising:
a vessel body;
at least one tray located in the vessel body;
a tube extending into the vessel body to a location beneath the at least one tray, the tube allowing communication between an interior of the vessel and a connected gas handling system;
a level sensor comprising:
at least one reed switch located on the tube; and
at least one toroidal magnet,
wherein the tube extends through an opening defined by the at least one toroidal magnet, such that the at least one toroidal magnet is slidably engaged with the tube;
wherein, when a solid precursor is loaded onto the at least one tray, the at least one toroidal magnet is configured to rest on a surface of the solid precursor;
wherein the level sensor is configured to sense changes in the location of the at least one toroidal magnet relative to the at least one reed switch to sense precursor levels within the vessel.

15. The vessel of claim 14, wherein the at least one toroidal magnet is enclosed in an inert material.

16. The vessel of claim 14, wherein the at least one toroidal magnet is enclosed in glass or stainless steel.

17. The vessel of claim 14, wherein the tube is configured for supplying a carrier gas to the location beneath the at least one tray.

18. The vessel of claim 14,
wherein the at least one tray comprises:
a first tray; and
a second tray;
wherein the at least one reed switch comprises:
a first reed switch; and
a second reed switch;
wherein the at least one toroidal magnet comprises:
a first toroidal magnet; and
a second toroidal magnet;
wherein the tube extends through a first opening defined by the first toroidal magnet and a second opening defined by the second toroidal magnet, such that the first toroidal magnet and the second toroidal magnet are independently slidably engaged with the tube;
wherein, when a solid precursor is loaded onto the first tray, the first toroidal magnet is configured to rest on a surface of the solid precursor loaded onto the first tray;
wherein, when a solid precursor is loaded onto the second tray, the second toroidal magnet is configured to rest on a surface of the solid precursor loaded onto the second tray;
wherein the level sensor is configured to sense changes in the location of the first toroidal magnet relative to the first reed switch to sense precursor levels on the first tray;
wherein the level sensor is configured to sense changes in the location of the second toroidal magnet relative to the second reed switch to sense precursor levels on the second tray.

19. The vessel of claim 14, wherein the at least one reed switch is mounted to an inner sidewall of the tube.

20. The vessel of claim 14, wherein an inner diameter of the at least one toroidal magnet is greater than an outer diameter of the tube.
